(19) United States
(12) Patent Application Publication
(10) Pub. No.: US 2024/0120444 A1
(43) Pub. Date: Apr. 11, 2024

(54) LIGHT EMITTING DEVICE AND METHOD FOR MANUFACTURING THE SAME

(71) Applicant: TIANJIN SANAN OPTOELECTRONICS CO., LTD., Tianjin (CN)

(72) Inventors: Wuqi SHEN, Tianjin (CN); Die HU, Tianjin (CN); Shaohua WU, Tianjin (CN); Lingfei WANG, Tianjin (CN); Zhendong NING, Tianjin (CN); Chen Kang HSIEH, Tianjin (CN); Chun-I CHANG, Tianjin (CN); Duxiang WANG, Tianjin (CN)

(21) Appl. No.: 18/543,468

(22) Filed: Dec. 18, 2023

Related U.S. Application Data
(63) Continuation-in-part of application No. PCT/CN2021/102005, filed on Jun. 24, 2021.

(51) Int. Cl. H01L 33/22; H01L 33/00

(52) U.S. Cl. CPC H01L 33/22; H01L 33/0062; H01L 33/30

(57) ABSTRACT

A light-emitting device includes a substrate, a semiconductor epitaxial structure, and an etch stop layer. The substrate has a first surface and a second surface opposite to the first surface. The semiconductor epitaxial structure has a side surface that has a roughened structure formed with protrusions, and includes a first type semiconductor layer, an active layer, and a second type semiconductor layer disposed on the first surface of the substrate in such order. The etch stop layer is disposed on a surface of the semiconductor epitaxial structure away from the substrate for preventing an etching solution from etching the semiconductor epitaxial structure. A light-emitting package and a light-emitting apparatus are also provided. A method for manufacturing a light-emitting device is also provided.

### CROSS-REFERENCE TO RELATED APPLICATION

This application is a continuation-in-part (CIP) of International Application No. PCT/CN2021/102005, filed on Jun. 24, 2021, which is incorporated herein by reference in its entirety.

### FIELD

The disclosure relates to a light-emitting device and a method for manufacturing the same.

### BACKGROUND

Light-emitting diodes (LEDs) are currently widely used in various fields of light source such as backlighting, illumination, landscape lighting, etc., for having advantages such as high luminous efficiency and long lifespan. Further improving the luminous efficiency of the LEDs is still a current focus of development in the industry.

The luminous efficiency of the LEDs may be increased by several ways, such as by increasing their internal quantum efficiency (IQE) and external quantum efficiency (EQE). In the case of increasing the IQE, by improving quality of epitaxial growth, recombination of electrons and holes may be increased, thereby increasing the IQE. In the case of increasing the EQE, if light emitted from the LEDs cannot be effectively extracted due to total internal reflection, a portion of the light is trapped inside the LEDs reflecting or refracting back and forth, and is ultimately absorbed by electrodes or an active layer, thereby limiting brightness. This may be alleviated by employing surface roughening or changing geometry of a surface structure, thereby increasing the EQE, and thus improving the brightness and the luminous efficiency of the LEDs.

The process of surface roughening improves the luminous efficiency of the LEDs by forming protrusions on a light-emitting surface to help scatter or guide the trapped light out of the LEDs, thereby increasing the portion of the light exiting the LEDs. Generally, a top surface or a side surface of an LED may be roughened to increase the EQE of the LED. During the roughening of the side surface, a certain degree of damage to a transparent conductive layer on a semiconductor epitaxial structure may occur due to strong acid solutions that are used. A silicon nitride layer is generally deposited on the top surface of the LED by chemical deposition to protect the transparent conductive layer. However, due to poor adhesion and poor compactness of the silicon nitride layer, the electrodes and the light-emitting surface of the LED may not be properly covered, which causes the strong acid solution to penetrate the silicon nitride layer and the transparent conductive layer, damaging the semiconductor epitaxial structure, thereby affecting the appearance quality and the photoelectric performance of the LED. Furthermore, since the silicon nitride layer needs to be removed by a solution such as hydrofluoric acid, some fluorine-containing residues may be left on the top surface of the LED, resulting in the top surface being prone to adsorption of contaminants, thereby affecting wire bonding of the LED.

### SUMMARY

Therefore, an object of the disclosure is to provide a light-emitting device, a light-emitting package, a light-emitting apparatus, and a method for manufacturing a light-emitting device that can alleviate at least one of the drawbacks of the prior art.

According to one aspect of the disclosure, the light-emitting device includes a substrate, a semiconductor epitaxial structure, and an etch stop layer. The substrate has a first surface and a second surface opposite to the first surface. The semiconductor epitaxial structure has a side surface that has a roughened structure formed with protrusions, and includes a first type semiconductor layer, an active layer, and a second type semiconductor layer disposed on the first surface of the substrate in such order. The etch stop layer is disposed on a surface of the semiconductor epitaxial structure away from the substrate for preventing an etching solution from etching the semiconductor epitaxial structure.

According to another aspect of the disclosure, the light-emitting package includes a base plate and at least one aforesaid light-emitting device disposed on the base plate.

According to yet another aspect of the disclosure, the light-emitting apparatus includes the aforesaid light-emitting device.

According to still yet another aspect of the disclosure, a method for manufacturing a light-emitting device includes: a) forming a semiconductor epitaxial structure on a substrate, the semiconductor epitaxial structure having a side surface and including a first type semiconductor layer, an active layer, and a second type semiconductor layer in such order on a first surface of the substrate; b) forming an etch stop layer on a surface of the semiconductor epitaxial structure away from the substrate; c) forming a transparent conductive layer on the etch stop layer away from the semiconductor epitaxial structure; d) forming a first electrode and a second electrode on the transparent conductive layer and the substrate, respectively; and e) etching the side surface of the semiconductor epitaxial structure using an etching solution so as to form a roughened structure on the side surface.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view of a conventional light-emitting device before a roughening process.

FIG. 2 is a schematic view of the conventional light-emitting device of FIG. 1 when an etchant is being applied.

FIG. 3 is a focused ion beam (FIB) microscopy of the conventional light-emitting after the roughening process.

FIG. 4 is a schematic view of a first embodiment of a light-emitting device according to the present disclosure.

FIG. 5 is a schematic view of a second embodiment of the light-emitting device according to the present disclosure.

FIGS. 6-8 are schematic views illustrating a method for manufacturing the second embodiment of the light-emitting device according to the present disclosure.

FIG. 9 is a schematic view of a third embodiment of the light-emitting device according to the present disclosure.

FIG. 10 is a schematic view of a fourth embodiment of the light-emitting device according to the present disclosure.

FIG. 11 is a schematic view of an embodiment of a light-emitting package according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

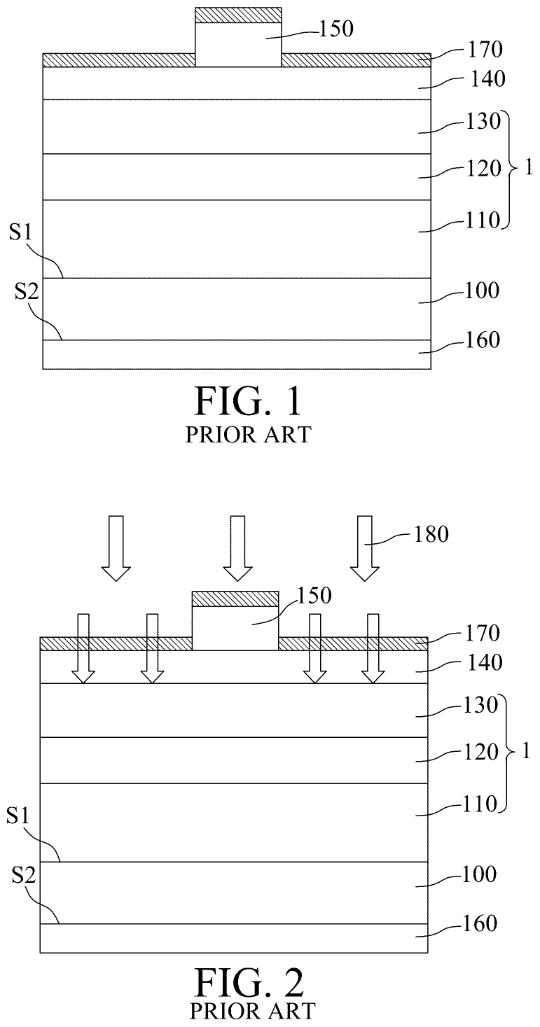

Referring to FIG. 1, a conventional light-emitting device may include a substrate 100, a semiconductor epitaxial structure 1, a transparent conductive layer 140, a first electrode 150, and a second electrode 160. The semiconductor epitaxial structure 1 includes a first type semiconductor layer 110, an active layer 120, and a second type semiconductor layer 130. The transparent conductive layer 140 is configured to spread current effectively. The first electrode 150 is formed on and covers a portion of the transparent conductive layer 140 so that another portion of the transparent conductive layer 140 is exposed from the first electrode 150. The second electrode 160 is formed on the substrate 100 opposite to the semiconductor epitaxial structure 1. To improve the external quantum efficiency (EQE) of the light-emitting device, the light-emitting device is subject to roughening of a side surface thereof by an etching solution so as to increase the luminous efficiency, as shown in FIG. 2. During such process, an etchant 180 may contact the transparent conductive layer 140 from a top surface of the light-emitting device and penetrates a top surface of the semiconductor epitaxial structure 1, causing a certain degree of damage to the transparent conductive layer 140 and the semiconductor epitaxial structure 1, thereby affecting the appearance quality and the photoelectric performance of the light-emitting device.

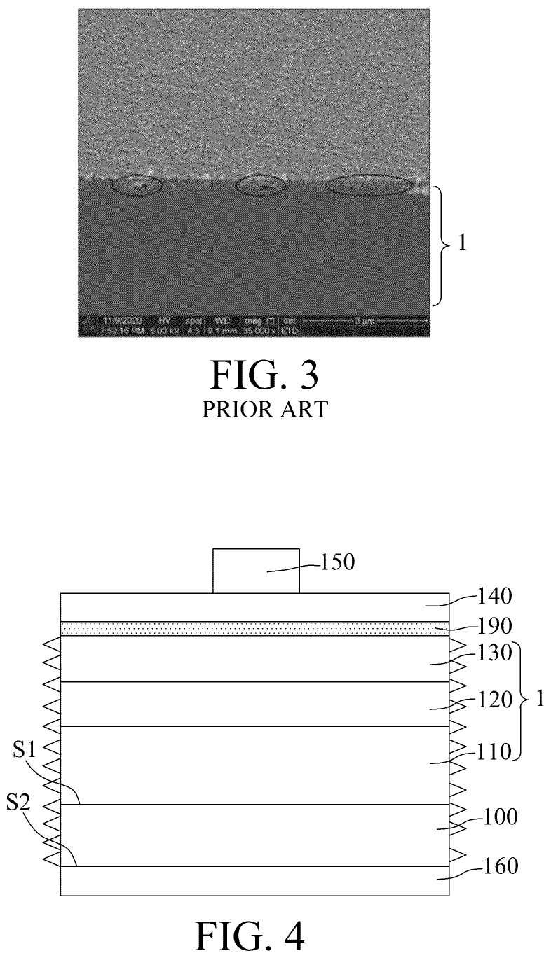

To alleviate the abovementioned problem, currently, plasma-enhanced chemical vapor deposition (PECVD) is used to deposit a silicon nitride layer 170 on the top surface of the light-emitting device, as shown in FIG. 1, to prevent the etchant 180 from damaging the transparent conductive layer 140 and the semiconductor epitaxial structure 1. However, since the silicon nitride layer 170 deposited by PECVD may have poor adhesion and poor compactness, and since a certain height difference exists between the first electrode 150 and the transparent conductive layer 140, the top surface of the light-emitting device may not be properly covered by the silicon nitride layer 170. As a result, the etchant 180 may still etch into the transparent conductive layer 140 or even the semiconductor epitaxial structure 1, thereby affecting the appearance quality of the light-emitting device. Since the etchant 180 may penetrate the silicon nitride layer 170 and the transparent conductive layer 140 and etch the top surface of the semiconductor epitaxial structure 1, some holes may be formed on the top surface of the semiconductor epitaxial structure 1, as shown in the circled portions of FIG. 3, thereby affecting the appearance quality and photoelectric performance of the light-emitting device.

In addition, depositing the silicon nitride layer 170 on the top surface of the light-emitting device has other drawbacks. For example, a hydrofluoric acid solution is often used to subsequently remove the silicon nitride layer 170 from the top surface of the light-emitting device, which causes some fluorine-containing residues to be left on the top surface of the light-emitting device, leading the top surface to be prone to adsorption of contaminants, thereby affecting a subsequent wire bonding of the light-emitting device.

In order to alleviate at least one of the abovementioned drawbacks, the present disclosure provides a light-emitting device and a method for manufacturing the same.

### First Embodiment

Referring to FIG. 4, a first embodiment of a light-emitting device according to the disclosure is provided and includes a substrate 100 having a first surface (S1) and a second surface (S2) opposite to the first surface (S1), a semiconductor epitaxial structure 1 including a first type semiconductor layer 110, an active layer 120, and a second type semiconductor layer 130disposed on the first surface (S1) of the substrate 100 in such order, a transparent conductive layer 140, a first electrode 150, a second electrode 160, and an etch stop layer 190.

Details for each layer are described below.

The substrate 100 is used for epitaxial growth and in certain embodiments is a commonly-used GaAs substrate. It should be noted that the substrate 100 is not limited to the GaAs substrate, other materials, such as GaP, InP, may also be used.

In the present embodiment, the substrate 100 is made of GaAs and may be a commercially-available single crystal substrate manufactured by known methods. In certain embodiments, the substrate has a smooth surface for epitaxial growth. In order to ensure a stable quality of the light-emitting device, in certain embodiments, the substrate 100 has a plane orientation conducive to epitaxial growth and mass production, such as a (100) plane and an orientation offset by up to ±20° from the (100) plane. In certain embodiments, a range of the plane orientation of the substrate 100 is 15°±5° offset from the (100) direction to the (0-1-1) direction.

In order for the semiconductor epitaxial structure 1 formed on the substrate 100 to have a good quality, in certain embodiments, the substrate 100 has a low dislocation density. Specifically, the dislocation density is no greater than 10,000/cm⁻², for example, no greater than 1,000/cm⁻². The substrate 100 may be an n-type GaAs substrate and may, typically, be doped with silicon (Si). In certain embodiments, the substrate 100 has a charge carrier concentration ranging from 1×10¹⁷ cm⁻³ to 5×10¹⁸ cm⁻³.

The substrate 100 has a thickness within a range appropriate to the size thereof. If the substrate 100 is too thin, the substrate 100 is prone to crack during manufacturing of the semiconductor epitaxial structure 1. On the other hand, if the substrate 100 is too thick, the material cost may be high. In certain embodiments, the substrate 100 has a large size, for example, a diameter of 75 mm, the thickness of the substrate 100 may range from 250 nm to 500 μm in order to prevent cracks from occurring during the manufacturing of the semiconductor epitaxial structure 1. In certain embodiments, the diameter of the substrate 100 is 50 mm, the thickness of the substrate 100 ranges from 200 μm to 400 μm. In certain embodiments, the diameter of the substrate 100 is 100 mm, the thickness of the substrate 100 ranges from 350 μm to 600 μm.

By increasing the thickness of the substrate 100 based on the size thereof, warpage of the semiconductor epitaxial structure 1 resulting from epitaxial growth may be reduced. In addition, the temperature distribution during epitaxial growth may become more evenly, so that light emitted inward from the active layer 120 may have an improved distribution in wavelength.

To reduce spreading of defects from the substrate 100 to the semiconductor epitaxial structure 1, and to improve crystal quality of the semiconductor epitaxial structure 1, a buffer layer (not shown) may be disposed between the substrate 100 and the semiconductor epitaxial structure 1. In certain embodiments, the buffer layer includes a material similar to that of the substrate 100 that is used for epitaxial growth. In the present embodiment, the buffer layer includes the same material as the substrate 100. In addition, in order to effectively reduce the spreading of defects, the buffer layer may have a multilayer structure that includes a material different from the material of the substrate 100. In certain embodiments, the buffer layer has a thickness not smaller than 0.1 μm. In certain other embodiments, the thickness of the buffer layer is not smaller than 0.2 μm.

The semiconductor epitaxial structure 1 may be obtained by metal organic chemical vapor deposition (MOCVD) or other growth methods. The semiconductor epitaxial structure 1 may include a material capable of providing radiations of light such as ultraviolet light, blue light, green light, yellow light, red light, infrared light, etc. Specifically, the material may radiate light with a wavelength ranging from 200 nm to 950 nm and may be nitride, for example. More specifically, the semiconductor epitaxial structure 1 may be a gallium nitride (GaN)-based semiconductor epitaxial structure that is generally doped with elements such as aluminum and indium, and provides radiation within a wavelength ranging from 200 nm to 550 nm. Alternatively, an aluminum gallium indium phosphide (AlGaInP)-based or aluminum gallium arsenide (AlGaAs)-based semiconductor epitaxial structure may provide radiation with a wavelength ranging from 550 nm to 950 nm.

The first type semiconductor layer 110 and the second type semiconductor layer 130 may respectively be n-type doped and p-type doped, and provide electrons and holes, respectively. An n-type semiconductor layer may be doped with n-type dopants such as Si, Ge, or Sn, and a p-type semiconductor layer may be doped with p-type dopants such as Mg, Zn, Ca, Sr, Ba, and C. The first type semiconductor layer 110, the active layer 120, and the second type semiconductor layer 130 may be formed from aluminum gallium indium nitride, gallium nitride, aluminum gallium nitride, aluminum indium phosphide, aluminum gallium indium phosphide, gallium arsenide or aluminum gallium arsenide. The first type semiconductor layer 110 or the second type semiconductor layer 130 may include a cladding sub-layer that provides electrons or holes, and some other sub-layers, such as a window sub-layer, or an ohmic contact sub-layer, etc. The sub-layers may have different doping concentrations or component contents. The active layer 120 is a region where the electrons and the holes recombine to provide light radiation. Materials for forming the active layer 120 may be determined according to the desired wavelength of light. The active layer 120 may have a single-quantum-well structure or a multiple-quantum-well structure including a sub-layer unit(s). By adjusting a composition ratio of the semiconductor materials used for forming the active layer 120, the active layer 120 may radiate light having various wavelengths.

In the present embodiment, the semiconductor epitaxial structure 1 includes a GaAs-based material and is capable of emitting infrared light. In the present embodiment, the first type semiconductor layer 110 includes AlGaAs, and the active layer 120 has a multiple-quantum-well structure that includes quantum well sub-layers and quantum barrier sub-layers stacked alternately. Each of the quantum well sub-layers and a corresponding one of the quantum barrier sub-layers that is adjacent to the each of the quantum well sub-layers constitute a sub-layer unit, and the number of the sub-layer units ranges from 5 to 15. Each of the quantum well sub-layers includes InGaAs and has a thickness ranging from 10 nm to nm. Each of the quantum barrier sub-layers includes AlGaAsP and has a thickness ranging from 3 nm to 15 nm. In certain embodiments, the second type semiconductor layer 130 includes AlGaAs.

The GaAs-based infrared light-emitting device has a relatively high transmittance in the GaAs material due to the wavelength of the light emitted, therefore every surface of the light-emitting device is a light-emitting surface. The side surface of the semiconductor epitaxial structure 1 may be roughened to form a roughened structure with protrusions, so as to improve the light extraction efficiency of the side surface and improve the luminous efficiency of the light-emitting device. In the present embodiment, the substrate includes a GaAs material, and a roughened structure is also formed on a side surface of the substrate.

As shown in FIG. 2, when roughening the side surface of the light-emitting device, a strong acid solution that is used penetrates the silicon nitride layer 170, even the transparent conductive layer 140, thus damaging the semiconductor epitaxial structure 1. Due to the characteristics of AlGaAs that is prone to react with and be etched by the strong acid solution, the top surface of the semiconductor epitaxial structure 1 made of AlGaAs may have an abnormal appearance, as shown in FIG. 3, thereby leading to a decrease in the yield of the light-emitting device.

In the present disclosure, the etch stop layer 190 is disposed on a surface of the semiconductor epitaxial structure 1 away from the substrate 100 for preventing an etchant from etching the semiconductor epitaxial structure 1. The etch stop layer 190 includes an acid-resistant material or an alkali-resistant conductive material. In some embodiments, the etch stop layer 190 may include an inert metal, such as Au, Ti, Pt, or the like.

In the present embodiment, the etch stop layer 190 includes a material represented by (Al_{X}Ga_{1-X})_{Y}|n_{1-Y}P, where 0≤X≤1 and 0≤Y≤1. In certain embodiments, the etch stop layer 190 includes a GaP material. Since the GaP material has good chemical stability, and thus is not prone to be etched by the etchant used in the roughening process. Moreover, the GaP material has a large band gap and good light transmittance for infrared light. Therefore, the luminous efficiency of the light-emitting device including the etch stop layer 190 remains unaffected. It should be noted that the material of the etch stop layer is not limited to GaP, and may be AlGaInP, GaInP, etc.

In certain embodiments, the etch stop layer 190 has a thickness of 30 nm to 150 nm. If the etch stop layer 190 is too thin, the etch stop layer 190 may not be able to effectively block the acid solution from etching the semiconductor epitaxial structure 1 in the roughening process. On the other hand, the material composition of the etch stop layer 190 being different from that of the semiconductor epitaxial structure 1 may cause a lattice mismatch therebetween. Therefore, in order to ensure the lattice quality of the semiconductor epitaxial structure 1 and the etch stop layer 190, the thickness of the etch stop layer 190 need not be too thick. In some embodiments, the thickness of the etch stop layer 190 ranges from nm to 150 nm. In the present embodiment, the thickness of the etch stop layer ranges from 50 nm to 100 nm.

The etch stop layer 190 is p-type doped. In certain embodiments, the etch stop layer 190 is doped by carbon (C). In certain embodiments, the etch stop layer 190 has a doping concentration of 1E19/cm⁻³. In certain embodiments, the doping concentration is not smaller than 1E19/cm⁻³. The etch stop layer 190 and the transparent conductive layer 140 may form an ohmic contact.

The transparent conductive layer 140 is disposed on the etch stop layer 190 opposite to the semiconductor epitaxial structure 1 for spreading current effectively. In certain embodiments, the transparent conductive layer 140 has a light transmittance not smaller than 70%, so as to allow light emitted from the semiconductor epitaxial structure 1 to pass through. In certain embodiments, the light transmittance of the transparent conductive layer 140 is not smaller than 90%. The transparent conductive layer 140 is an ITO layer or an IZO layer. In the present embodiment, the transparent conductive layer 140 is an ITO layer.

The light-emitting device includes a first electrode 150 that is disposed on the transparent conductive layer 140 and covers a portion of the transparent conductive layer 140. In some embodiments, the first electrode 150 includes an electrode pad and an extension electrode. The electrode pad is configured for external wire bonding during packaging. The electrode pad may be designed, according to actual requirements for wire bonding, to have a shape, such as cylindrical, block, or, among others, polygonal shapes. The extension electrode may be formed with a predetermined pattern, and may be configured to have various shapes, such as a strip.

The light-emitting device further includes a second electrode 160. In the present embodiment, the second electrode 160 is disposed on the substrate 100 opposite to the semiconductor epitaxial structure 1 and completely covers the second surface (S2) of the substrate 100. In the present embodiment, the substrate 100 is an electrically conductive substrate. The first electrode 150 and the second electrode 160 are formed on opposite sides of the substrate 100 to enable current to flow vertically through the semiconductor epitaxial structure 1, thereby achieving a uniform current density.

In certain embodiments, each of the first electrode 150 and the second electrode 160 includes a metal material, and the metallic material includes one or more of Au, Ge, Ni, Cr, Al, Cu, Ti, Pt, and Zn.

In the present disclosure, the etch stop layer 190 prevents the etching of the top surface of the semiconductor epitaxial structure 1 during roughening of the side surface of the light-emitting device, thereby improving the appearance quality and photoelectric performance of the light-emitting device. On the other hand, the etch stop layer 190 eliminates the need for the silicon nitride layer as in the prior art, thus leaving the wire bonding process unaffected by the residues that may result from the removal of the silicon nitride layer.

### Second Embodiment

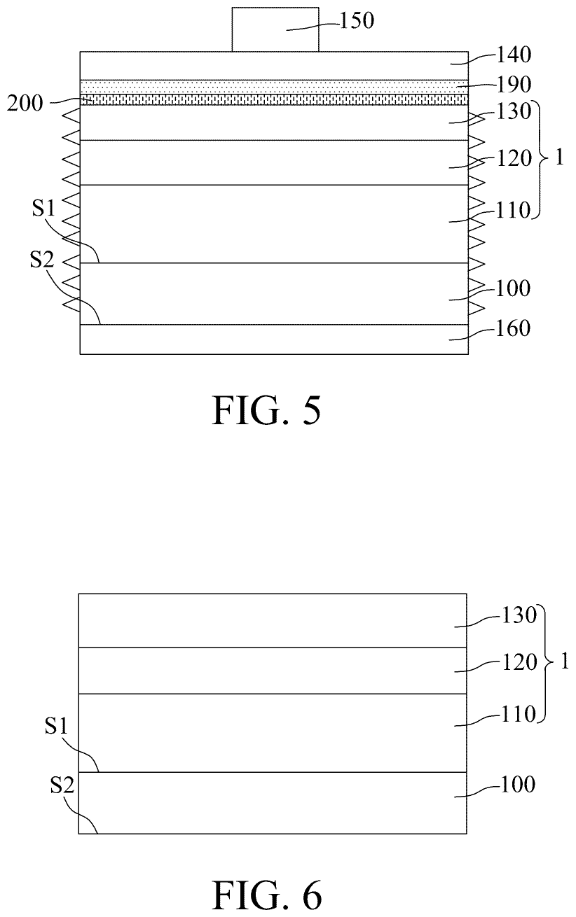

To improve the lattice quality of the semiconductor epitaxial structure 1 and the etch stop layer 190 while reducing the lattice mismatch between the semiconductor epitaxial structure 1 and the etch stop layer 190, a second embodiment of the light-emitting device according to the disclosure may further include an intermediate layer 200 disposed between the semiconductor epitaxial structure 1 and the etch stop layer 190, as shown in FIG. 5. The intermediate layer 200 may have a lattice constant between a lattice constant of the semiconductor epitaxial structure 1 and a lattice constant of the etch stop layer 190.

In some embodiments, the intermediate layer 200 includes a GaInP material and has a thickness of 20 nm to 50 nm. By including the intermediate layer 200, the lattice mismatch between the semiconductor epitaxial structure 1 and the etch stop layer 190 is reduced and the crystal quality of the etch stop layer 190 is improved, thereby improving the luminous efficiency of the light-emitting device.

A method for manufacturing the second embodiment of the light-emitting device according to the disclosure is described in detail below.

First, as shown in FIG. 6, the substrate 100 having the first surface (S1) and the second surface (S2) opposite to the first surface (S1) is provided. In certain embodiments, the substrate 100 is a GaAs substrate. Next, the semiconductor epitaxial structure 1 is formed on the substrate 100. The semiconductor epitaxial structure 1 has the side surface and includes the first type semiconductor layer 110, the active layer 120, and the second type semiconductor layer 130 formed in such order on the first surface (S1) of the substrate 100. Specifically, these layers are sequentially grown using MOCVD. In some embodiments, the semiconductor epitaxial structure 1 may include an n-type semiconductor layer, a quantum well layer, and a p-type semiconductor layer formed in such order. In some embodiments, the n-type semiconductor layer includes an n-type buffer sub-layer and an n-type confining sub-layer formed in such order. In the present embodiment, the n-type buffer layer is a GaAs buffer layer, which may greatly improve the growth quality of the semiconductor epitaxial structure 1 and the luminous efficiency of the light-emitting device. The n-type confining sub-layer is an n-type AlGaAs confining sub-layer. The quantum well layer has the multiple-quantum-well structure including the sub-layer unit(s) that includes the quantum well sub-layers and the quantum barrier sub-layers stacked alternately. Each of the quantum well sub-layers and the corresponding one of the quantum barrier sub-layers that is adjacent to the each of the quantum well sub-layers constitute the sub-layer unit, and the number of the sub-layer units ranges from 5 to 15. Each of the quantum well sub-layers includes InGaAs and has the thickness ranging from 10 nm to 20 nm. Each of the quantum barrier sub-layers includes AlGaAsP and has the thickness ranging from 3 nm to 15 nm. The p-type semiconductor layer includes a p-type confining sub-layer and a p-type window sub-layer, in which the p-type confining sub-layer is a p-type AlGaAs confining sub-layer and the p-type window sub-layer is an AlGaAs window sub-layer. It should be noted that AlGaAs refers to a material represented by AlₓGa₁₋ₓAs, where 0≤X≤1, and components for each layer and sub-layer that includes the material represented by AlₓGa₁₋ₓAs may be independently adjusted according to actual requirements.

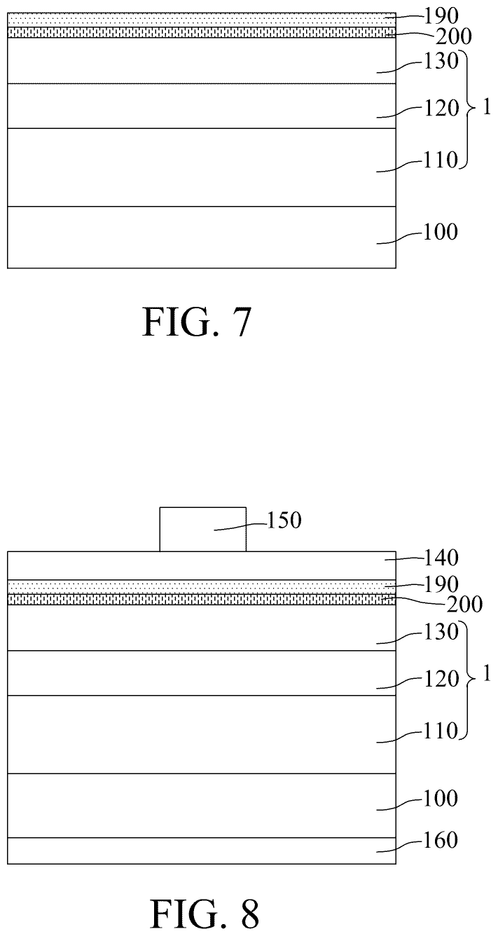

Then, as shown in FIG. 7, the intermediate layer 200 and the etch stop layer 190 are formed in such order on the surface of the semiconductor epitaxial structure 1 away from the substrate 100. Specifically, these layers are sequentially grown using MOCVD. In the present embodiment, the intermediate layer 200 includes the GaInP material and has a thickness of 20 nm to 50 nm, the etch stop layer 190 includes the GaP material and has a thickness of 30 nm to 150 nm. In some embodiments, the thickness of the etch stop layer 190 ranges from 50 nm to 100 nm. The etch stop layer 190 is p-type doped. In certain embodiments, the etch stop layer 190 is doped with carbon (C). In certain embodiments, the doping concentration of the etch stop layer 190 is not smaller than 1E19/cm⁻³. In certain embodiments, the doping concentration of the etch stop layer 190 is not smaller than 3E19/cm⁻³.

Next, as shown in FIG. 8, the transparent conductive layer 140 is formed on the etch stop layer 190 away from the semiconductor epitaxial structure 1. In certain embodiments, the transparent conductive layer 140 is an ITO layer or an IZO layer. In the present embodiment, the transparent conductive layer 140 is an ITO layer. A first electrode 150 and a second electrode 160 are then formed on the transparent conductive layer 140 and the substrate 100, respectively, thereby obtain a chip unit which includes the first electrode 150, the second electrode 160, the substrate 100, the semiconductor epitaxial structure 1, the intermediate layer 200, etch stop layer 190, and transparent conductive layer 140.

Finally, the side surface of the semiconductor epitaxial structure 1 is roughened by an acid solution in a roughening treatment to obtain the light-emitting device shown in FIG. 5. In some embodiments, a wafer (not shown) is formed with a plurality of the chip units, and the wafer is subjected to a dicing process to separate the chip units, and then the separated chip units are transferred onto a supporting substrate (not shown) for the roughening treatment. Specifically, the separated chip units are placed in an etchant for 3 seconds to 200 seconds for roughening, so as to obtain a plurality of the light-emitting devices (see FIG. 5) each having a roughened side surface. In certain embodiments, the etchant may be one or more of hydrofluoric acid, sulfuric acid, nitric acid, hydrochloric acid and phosphoric acid. In certain embodiments, the etchant has a concentration ranging from 50% to 100%. In the present embodiment, the etchant is nitric acid and has a concentration of 100%. The period during which the separated chip units are placed in the etchant is 50 seconds.

The method for manufacturing the light-emitting device described in the present embodiment is capable of effectively preventing the top surface of the light-emitting device from being unintentionally etched, thereby ensuring the appearance quality and the luminous efficiency of the light-emitting device.

### Third Embodiment

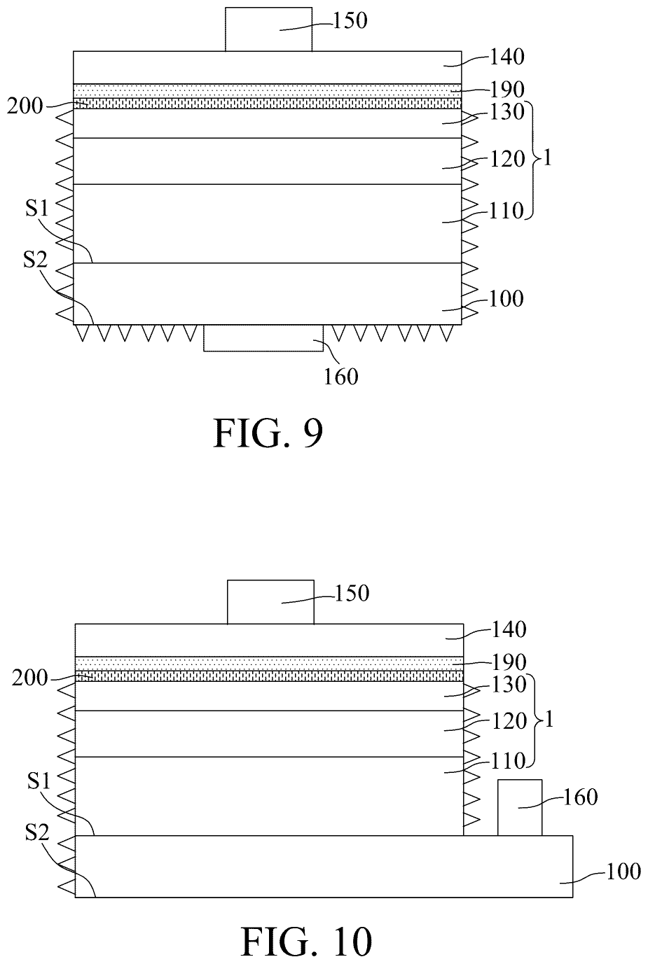

FIG. 9 is a schematic view of a third embodiment of the light-emitting device according to the present disclosure. The difference between the third embodiment the second embodiment resides in that, as shown in FIG. 9, the second electrode 160 of the light-emitting device does not completely cover the second surface (S2) of the substrate 100, instead a portion of the second surface (S2) is exposed. In the present embodiment, the second surface (S2) not covered by the second electrode 160 is formed with a roughened structure, which may further improve the luminous efficiency of the light-emitting device.

### Fourth Embodiment

FIG. 10 is a schematic view of a fourth embodiment of the light-emitting device according to the present disclosure. The difference between the fourth embodiment and the second embodiment resides in that, as shown in FIG. 10, in this embodiment, the second electrode 160 of the light-emitting device does not cover the second surface (S2) of the substrate 100, instead is disposed next to the side surface of the semiconductor epitaxial structure 1 and on the first surface (S1) of the substrate 100. Such structure also suffers from the unwanted etching of the semiconductor epitaxial structure 1 during the roughening of the side surface of the light-emitting device, which is addressed in the present embodiment by adding the etch stop layer 190 and optionally the intermediate layer 200.

In summary, the disclosure provides the light-emitting device and the method for manufacturing the same. The light-emitting device includes the substrate 100 having the first surface (S1) and the second surface (S2) opposite to the first surface (S1); a semiconductor epitaxial structure 1 having the side surface that has the roughened structure formed with protrusions, the semiconductor epitaxial structure including the first type semiconductor layer 110, the active layer 120, and the second type semiconductor layer 130 disposed on the first surface (S1) of the substrate in such order; and the etch stop layer 190 disposed on the surface of the semiconductor epitaxial structure 1 away from the substrate 100. In the present disclosure, the etch stop layer 190 prevents the etching of the top surface of the semiconductor epitaxial structure 1 during the roughening of the side surface of the light-emitting device and improves the appearance quality and photoelectric performance of the light-emitting device. On the other hand, the etch stop layer 190 eliminates the need for the silicon nitride layer 170 as in the prior art, thus the wire bonding process is unaffected by the residues that may result from the removal of the silicon nitride layer 170.

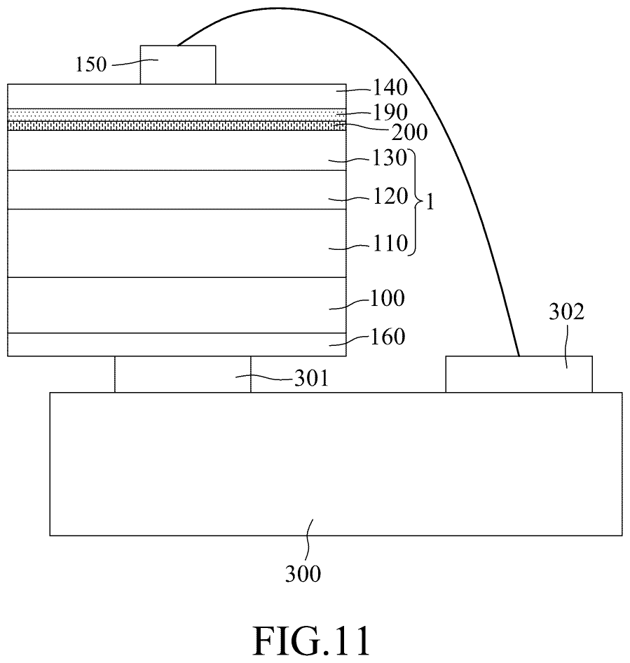

Referring to FIG. 11, a light-emitting package according to the disclosure is also provided and includes a base plate 300 (i.e., a packaging substrate) and at least one of the aforesaid light-emitting devices disposed on the base plate 300. Please note that in the embodiment shown in FIG. 11, the at least one light-emitting device is exemplified as that shown in FIG. 5 or 8, while in other embodiments, other light-emitting devices shown in FIGS. 4, 9 and 10 may be disposed on the base plate 300. The light-emitting package further includes a third electrode 301 and a fourth electrode 302 disposed on the base plate 300. The second electrode 160 is disposed on and electrically connected to the third electrode 301, and the first electrode 150 is electrically connected to the fourth electrode 302 by wire bon ding. A light-emitting apparatus according to the disclosure is also provided and includes any one of the aforesaid light-emitting devices.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, the one or more features may be singled out and practiced alone without the another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a substrate having a first surface and a second surface opposite to said first surface;
a semiconductor epitaxial structure having a side surface that has a roughened structure formed with protrusions, said semiconductor epitaxial structure including a first type semiconductor layer, an active layer, and a second type semiconductor layer disposed on said first surface of said substrate in such order; and
an etch stop layer disposed on a surface of said semiconductor epitaxial structure away from said substrate for preventing an etching solution from etching said semiconductor epitaxial structure.

2. The light-emitting device according to claim 1, wherein said etch stop layer includes an acid-resistant material or an alkali-resistant conductive material.

3. The light-emitting device according to claim 1, wherein said etch stop layer includes a material represented by (Al_{X}Ga_{1-X})_{Y}|n_{1-Y}P, where 0≤X≤1 and 0≤Y≤1.

4. The light-emitting device according to claim 1, wherein said etch stop layer includes a GaP material.

5. The light-emitting device according to claim 4, wherein said etch stop layer has a thickness of 30 nm to 150 nm.

6. The light-emitting device according to claim 4, wherein said etch stop layer has a thickness of 50 nm to 100 nm.

7. The light-emitting device according to claim 4, wherein said etch stop layer is p-type doped and has a doping concentration not smaller than 1E19/cm⁻³.

8. The light-emitting device according to claim 1, wherein said semiconductor epitaxial structure is capable of emitting infrared light.

9. The light-emitting device according to claim 1, wherein said semiconductor epitaxial structure includes a GaAs-based material.

10. The light-emitting device according to claim 1, further comprising an intermediate layer between said semiconductor epitaxial structure and said etch stop layer, said intermediate layer having a lattice constant between a lattice constant of said semiconductor epitaxial structure and a lattice constant of said etch stop layer.

11. The light-emitting device according to claim 9, wherein said intermediate layer includes a GaInP material.

12. The light-emitting device according to claim 9, wherein said intermediate layer has a thickness of 20 nm to 50 nm.

13. The light-emitting device according to claim 1, further comprising:
a transparent conductive layer disposed on said etch stop layer opposite to said semiconductor epitaxial structure.

14. The light-emitting device according to claim 12, wherein said transparent conductive layer has a light transmittance not smaller than 70%.

15. The light-emitting device according to claim 12, wherein said transparent conductive layer is an ITO layer or an IZO layer.

16. The light-emitting device according to claim 1, wherein said substrate is an electrically conductive substrate.

17. The light-emitting device according to claim 13, further comprising a first electrode and a second electrode that are disposed on said transparent conductive layer and said substrate, respectively.

18. A light-emitting package, comprising:
a base plate; and
at least one light-emitting device according to claim 1 disposed on said base plate.

19. A light-emitting apparatus, comprising a light-emitting device according to claim 1.

20. A method for manufacturing a light-emitting device, comprising:
a) forming a semiconductor epitaxial structure on a substrate, the semiconductor epitaxial structure having a side surface and including a first type semiconductor layer, an active layer, and a second type semiconductor layer in such order on a first surface of the substrate;
b) forming an etch stop layer on a surface of the semiconductor epitaxial structure away from the substrate;
c) forming a transparent conductive layer on the etch stop layer away from the semiconductor epitaxial structure;
d) forming a first electrode and a second electrode on the transparent conductive layer and the substrate, respectively; and
e) etching the side surface of the semiconductor epitaxial structure using an etching solution so as to form a roughened structure on the side surface.
